(19) United States
(12) Patent Application Publication
(10) Pub. No.: US 2024/0387325 A1
(43) Pub. Date: Nov. 21, 2024

(54) POWER ELECTRONIC SYSTEM INCLUDING A SEMICONDUCTOR MODULE AND A COOLER AND METHOD FOR FABRICATING THE SAME

(71) Applicant: Infineon Technologies AG, Neubiberg (DE)

(72) Inventors: Andreas Grassmann, Sinzing (DE); Steffen Hartmann, Bad Sassendorf (DE)

(21) Appl. No.: 18/652,146

(22) Filed: May 1, 2024

(30) Foreign Application Priority Data
May 15, 2023 (DE) 102023204526.5

(51) Int. Cl. H01L 23/473; H01L 23/00; H01L 23/31; H01L 23/498; H01L 25/065

(52) U.S. Cl. CPC H01L 23/473; H01L 23/3121; H01L 23/49833; H01L 23/49838; H01L 24/08; H01L 24/80; H01L 25/0655; H01L 2224/08225; H01L 2224/8084; H01L 2224/80895; H01L 2924/1815

(57) ABSTRACT

A power electronic system includes a semiconductor module that includes a power electronic substrate having opposite first and second sides, power semiconductor die arranged over the second side of the substrate, and an encapsulation encapsulating the power semiconductor dies. The first side of the power electronic substrate is at least partially exposed from a first side of the encapsulation. The semiconductor module is arranged over an exterior surface of a wall of a cooler configured for fluidic cooling, such that the first side of the power electronic substrate faces the wall. The cooler includes cooling structures arranged on an interior surface of the wall. A first portion of the wall directly below the power electronic substrate has a first wall thickness and a second portion of the wall laterally next to the first portion has a second wall thickness, the first wall thickness being greater than the second wall thickness.

### TECHNICAL FIELD

This disclosure relates in general to a power electronic system comprising a semiconductor module and a cooler, in particular a cooler with a wall with a first wall thickness and a different second wall thickness, as well as to a method for fabricating such a power electronic system.

### BACKGROUND

A power comprise a electronic system may semiconductor module and a cooler, wherein the semiconductor module is coupled to the cooler. During operation, one or more power semiconductor dies of the semiconductor module may generate heat which may be dissipated via the cooler. Fabricating such a power electronic system may for example comprise coupling the semiconductor module to the cooler using a soldering process or a sintering process. However, the coefficients of thermal expansion of the semiconductor module on the one hand and the cooler on the other hand may exhibit a mismatch. This mismatch may cause significant thermo-mechanical stress in the semiconductor module, for example during cooldown after the soldering process or sintering process. Mechanical and/or electrical failure of the semiconductor module may be the consequence of this thermo-mechanical stress. Improved power electronic systems as well as improved methods for fabricating power electronic systems may help in solving these and other problems.

### SUMMARY

Various aspects pertain to a power electronic system, comprising: a semiconductor module, comprising: at least a first power electronic substrate comprising a first side and an opposite second side, at least a first and a second power semiconductor die arranged over the second side of the first power electronic substrate, and an encapsulation encapsulating the first and second power semiconductor dies, wherein the first side of the first power electronic substrate is at least partially exposed from a first side of the encapsulation; and a cooler configured for fluidic cooling, wherein the semiconductor module is arranged over an exterior surface of a wall of the cooler, such that the first side of the first power electronic substrate faces the wall, wherein the cooler comprises a plurality of cooling structures arranged on an interior surface of the wall, and wherein a first portion of the wall directly below the first power electronic substrate has a first wall thickness and a second portion of the wall laterally next to the first portion has a second wall thickness, the first wall thickness being greater than the second wall thickness.

Various aspects pertain to a method for fabricating a power electronic system, the method comprising: providing a semiconductor module, comprising: at least a first power electronic substrate comprising a first side and an opposite second side, at least a first and a second power semiconductor die arranged over the second side of the first power electronic substrate, and an encapsulation encapsulating the first and second power semiconductor dies, wherein the first side of the first power electronic substrate is at least partially exposed from a first side of the encapsulation; providing a cooler configured for fluidic the cooling; and arranging semiconductor module over an exterior surface of a wall of the cooler, such that the first side of the first power electronic substrate faces the cooler, wherein the cooler comprises a plurality of cooling structures arranged on an interior surface of the wall, and wherein a first portion of the wall directly below the first power electronic substrate has a first wall thickness and a second portion of the wall laterally next to the first portion has a second wall thickness, the first wall thickness being greater than the second wall thickness.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIG. 1 shows a sectional view of an exemplary power electronic system comprising a semiconductor module and a cooler, wherein a wall of the cooler has a first portion with a first wall thickness and a second portion with a different second wall thickness.

FIG. 2 shows a plan view of a semiconductor module configured to be coupled to a cooler.

FIG. 3 shows a plan view of a cooler comprising a plurality of first portions with the first wall thickness.

FIG. 4 shows a sectional view of a further power electronic system, wherein the wall of the cooler has the second wall thickness only in specific portions below and around the semiconductor module.

FIG. 5 shows a sectional view of a further power electronic system, wherein the first portions with the first wall thickness are arranged below the footprints of the power semiconductor dies of the semiconductor module.

FIG. 6 shows a sectional view of a further power electronic system, wherein the semiconductor module comprises an external contact.

FIG. 7 is a flow chart of an exemplary method for fabricating a power electronic system.

### DETAILED DESCRIPTION

In the following detailed description, directional terminology, such as “top”, “bottom”, “left”, “right”, “upper”, “lower” etc., is used with reference t to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless of whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a semiconductor module mentioned below may use various types of semiconductor dies or circuits incorporated in the semiconductor dies, among them AC/DC or DC/DC converter circuits, power MOSFET transistors, power Schottky diodes, (Junction JFETs Gate Field Effect Transistors), power bipolar transistors, logic integrated circuits, power integrated circuits, etc. The examples may also use semiconductor dies comprising MOSFET transistor structures or vertical transistor structures like, for example, IGBT (Insulated Gate Bipolar Transistor) structures or, in general, transistor structures in which at least one electrical contact pad is arranged on a first main face of the semiconductor die and at least one other electrical contact pad is arranged on a second main face of the semiconductor die, opposite to the first main face.

An efficient power electronic system as well as an efficient method for fabricating a power electronic system may for example reduce material consumption, ohmic losses, chemical waste, etc. and may thus enable energy and/or resource savings. Improved power electronic systems as well as improved methods for fabricating a power electronic system, as specified in this description, may thus at least indirectly contribute to green technology solutions, i.e. climate-friendly solutions providing a mitigation of energy and/or resource use.

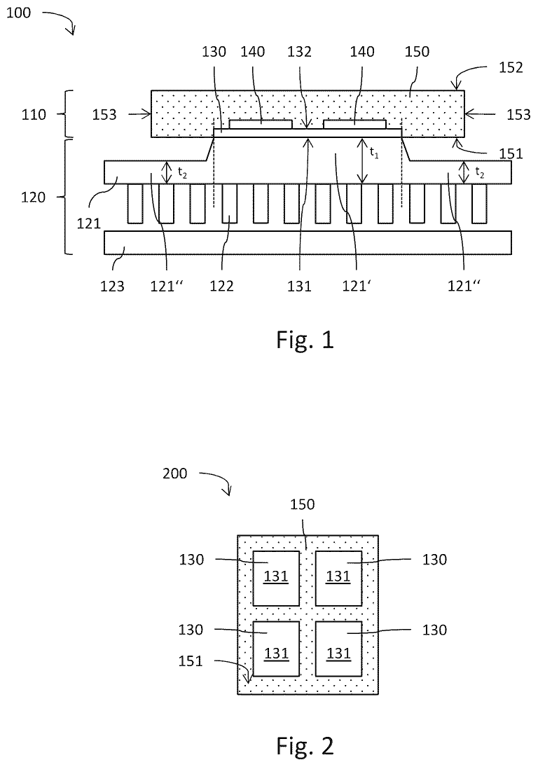

FIG. 1 shows a sectional view of a power electronic system 100 comprising a semiconductor module 110 arranged on a cooler 120.

The semiconductor module 110 comprises at least a first power electronic substrate 130, at least a first and a second power semiconductor die 140 and an encapsulation 150. According to an example, the power electronic system 100 comprises a single semiconductor module 110. According to another example, the power electronic system 100 may comprise two, three, four, five, etc. semiconductor modules 110 which may for example be arranged side by side on the cooler 120. The more than one semiconductor modules 110 may be identical modules or different types of modules.

The semiconductor module 110 may be a power module, configured to operate with a high electrical current and/or a high electrical voltage. The one or more semiconductor modules 110 of the power electronic system 100 may comprise any suitable electrical circuitry, for example a converter circuitry, an inverter circuitry, a half bridge circuitry, a full bridge circuitry, etc. The more than one semiconductor modules 110 of the power electronic system 100 may be electrically connected in order to provide the desired circuitry.

The semiconductor module 110 may comprise a single power electronic substrate 130 or more than one power electronic substrates, e.g. two, three, four, etc. The power electronic substrate(s) 130 comprise a first side 131 and an opposite second side 132.

The power electronic substrate 130 may for example be a substrate of the type leadframe, direct copper bonded (DCB), direct aluminum bonded (DAB), active metal brazed (AMB), insulated metal substrate (IMS) or printed circuit board (PCB). The power electronic substrate 130 may for example comprise or consist of Al, Cu or an alloy thereof.

The power electronic substrate 130 comprises a first side 131 and an opposite second side 132. The first side 131 may face the cooler 120 and the second side 132 may face away from the cooler 120. The at least first and a second power semiconductor dies 140 are arranged over the second side 132 of the first power electronic substrate 130.

The first and second power semiconductor dies 140 may be identical dies or may have different dimensions and/or different properties. The first and second power semiconductor dies 140 may for example be electrically connected, in particular via the power electronic substrate 130.

The encapsulation 150 encapsulates the first and second power semiconductor dies 140. The encapsulation 150 may be configured to protect the power semiconductor dies 140 from environmental influences. The encapsulation 150 may for example comprise or consist of one or more of a molded body, a plastic frame and a potting material. A molded body may for example be fabricated using a technique like compression molding, injection molding or transfer molding. A molded body may comprise inorganic filler particles configured to reduce the thermal resistance of the encapsulation 150.

The encapsulation 150 may comprise a first side 151 and an opposite second side 152, wherein the first side 151 faces the cooler 120. The encapsulation 150 may also comprise lateral sides 153 connecting the first and second sides 151, 152. The first side 131 of the first power electronic substrate 130 is at least partially exposed from the first side 151 of the encapsulation 150. In the example shown in FIG. 1, the first side 131 of the power electronic substrate 130 is completely exposed from the first side 151 of the encapsulation 150.

According to an example, the first sides 131, 151 of the power electronic substrate 130 and the encapsulation 150 may be essentially coplanar. According to another example, the first side 131 of the power electronic substrate 130 may (slightly) protrude from or be (slightly) recessed with respect to the first side 151 of the encapsulation 150.

The cooler 120 is configured for fluidic cooling. In other words, the cooler 120 may provide a fluid channel configured to hold a cooling fluid. The cooling fluid may for example be or comprise water or air. The power electronic system 100 may employ a direct fluidic cooling scheme, wherein the semiconductor module 110 is directly coupled to the cooler 120 (without a layer of thermal interface material separating the semiconductor module 110 from the cooler 120). The cooler 120 may comprise or consist of any suitable material. For example, the cooler 120 may comprise or consist of a metal or an alloy and may for example comprise or consist of Al or Cu.

The semiconductor module 110 is arranged over an exterior surface of a wall 121 of the cooler 120, such that the first side 131 of the power electronic substrate 130 faces the wall 121. The semiconductor module 110 (in particular, the first side 131 of the power electronic substrate 130) may for example be coupled to the exterior surface of the wall 121 via a soldered bond, a sintered bond or a bond comprising glue. Additionally or alternatively, the semiconductor module 110 may be fastened to the cooler 120 by mechanical means, e.g. screws or rivets.

The cooler 120 comprises a plurality of cooling structures 122 arranged on an interior surface of the wall 121. The cooling structures 122 may for example comprise or consist of pin fins. The cooling structures 122 may be configured to be in direct contact with a cooling fluid within the cooler 120. The cooling structures 122 and the wall 121 may be a single piece part or the cooling structures 122 may be coupled to the wall 121.

The cooler 120 may comprise a second wall 123 opposite the wall 121, wherein the walls 121 and 123 form an interior volume, i.e. a fluid channel, wherein the cooling structures 122 are arranged within the interior volume (for example, the walls 121, 123 may be half shelfs forming the fluid channel).

As shown in FIG. 1, a first portion 121′ of the wall 121 directly below the power electronic substrate 130 has a first wall thickness t₁ and a second portion 121″ of the wall 121 laterally next to the first portion 121′ has a second wall thickness to, wherein the first wall thickness t₁ is greater than the second wall thickness t₂.

In the example shown in FIG. 1, the first portion 121′ comprises a plateau with the greater wall thickness t₁ which protrudes from the second portion 121″ with the smaller wall thickness t₂ at the exterior surface of the wall 121. The transition from the first wall thickness t₁ to the second wall thickness t₂ may for example be a sharp transition, meaning that the transition comprises a vertical or almost vertical step. However, it is also possible that the transition is a gradual transition.

The above-used term “directly below the power electronic substrate” may mean that the first portion 121′ is essentially arranged below a footprint of the power electronic substrate 130 (the footprint is indicated by dashed lines in FIG. 1). As shown in FIG. 1, lateral sides of first portion 121′ may have a slope and may therefore slightly protrude from the footprint of the power electronic substrate 130. However, a first portion 121′ with such a form may still be considered to be arranged “within the footprint” of the power electronic substrate 130.

According to an example, the first portion 121′ of the wall 121 has essentially the same footprint as the power electronic substrate 130. In the case that the semiconductor module 110 comprises more than one power electronic substrate 130, each one of the power electronic substrates 130 may be arranged on a separate first portion 121′ of the wall 121. According to an example, the first portion 121′ is completely surrounded by the second portion 121″. According to an example, the first portion 121′ and the second portion 121″ comprise or consist of the same material or material composition (in this case, both portions 121′ and 121″ may be portions of a single piece). According to another example, the first portion 121′ and the second portion 121″ have different materials or material compositions (in this case, the portions 121′ and 121″ may be two pieces coupled together to form the wall 121).

The first wall thickness t₁ may for example be in the range of about 2 mm to about 5 mm. The lower limit of this range may also be about 2.5 mm or about 3 mm and the upper limit may also be about 4.5 mm, about 4 mm or about 3.5 mm. The second wall thickness t₂ may for example be in the range of about 0.5 mm to about 1.8 mm. The lower limit of this range may also be about 1 mm or about 1.5 mm and the upper limit may also be about 1.5 mm. According to an example, a difference between the first wall thickness t₁ and the second wall thickness t₂ is in the range of about 1 mm to about 4 mm. The lower limit of this range may also be about 1.5 mm or 2 mm and the upper limit of this range may also be about 3.5 mm, about 3 mm or about 2.5 mm.

The semiconductor module 110 on the one hand and the cooler 120 on the other hand may exhibit a mismatch in the coefficient of thermal expansion. If the wall 121 was comparatively rigid, this mismatch could induce significant strain into the semiconductor module 110, for example during cooldown after sintering or soldering the module 110 to the cooler 120. By reducing the wall thickness in the second portion 121″, the flexibility of the wall 121 is increased and the strain introduced into the semiconductor module 110 can be reduced or even eliminated. The first portion 121′ on the other hand is thick enough to withstand an increased pressure during the sintering process.

According to the example shown in FIG. 1, the transition between the greater wall thickness t₁ and the smaller wall thickness t₂ is arranged at the exterior surface of the wall 121. The interior surface of the wall 121 may be essentially level. This may for example prevent a negative impact on the flow of a cooling fluid within the cooler 120.

FIG. 2 shows a plan view of a semiconductor module 200 which may be similar or identical to the semiconductor module 110, except for the differences described in the following.

The semiconductor module 200 comprises more than one power electronic substrate 130. In the example shown in FIG. 2, the semiconductor module 200 comprises four power electronic substrates 130 arranged in a matrix. However, the semiconductor module 200 may comprise any suitable number of power electronic substrates 130 and the power electronic substrates 130 may be arranged in any suitable pattern.

In the example shown in FIG. 2, all power electronic substrates 130 essentially have an identical shape and identical dimensions. It is however also possible that one or more or even all of the power semiconductor substrates 130 have a different shape and/or different dimensions.

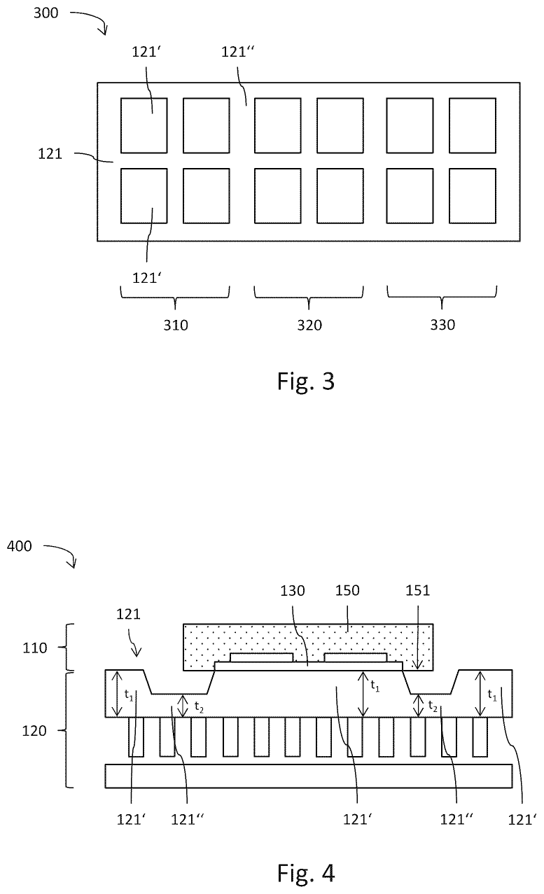

FIG. 3 shows a plan view of a cooler 300 which may be similar or identical to the cooler 120, except for the differences described in the following.

In particular, the wall 121 of the cooler 300 comprises more than one first portion 121′ with the greater wall thickness t₁. The more than one first portions 121′ may for example be arranged in a matrix. According to an example, at least some of the first portions 121′ may have essentially the same shape, same dimensions and the same alignment as the power electronic substrates 130 of the semiconductor module 200. In this manner, each of the power electronic substrates 130 of the semiconductor module 200 may be coupled to an individual first portion 121′ of the cooler 300.

In the example shown in FIG. 3, the cooler 300 comprises a first group of first portions 310, a second group of first portions 320 and a third group of first portions 330. The cooler 300 may be configured to have a first semiconductor module coupled to the first group 310, to have a second semiconductor module coupled to the second group 320 and to have a third semiconductor module coupled to the third group 330. In other words, three semiconductor modules may be arranged on the cooler 300 side by side. This is of course only an example and the cooler 300 may be configured to be coupled to any suitable number of semiconductor modules, e.g. one, two, three, four, five, etc.

FIG. 4 shows a sectional view of a further power electronic system 400 which may be similar or identical to the power electronic system 100, except for the differences described in the following.

In particular, in the power electronic system 400 the wall 121 of the cooler 120 has the greater wall thickness t₁ not only directly below the power electronic substrate 130. Instead, first portions 121′ with the greater wall thickness t₁ are also arranged laterally next to the semiconductor module 110. However, at least a portion of the wall 121 arranged within a footprint of the first side 151 of the encapsulation 150 has the second wall thickness t₂.

According to the example shown in FIG. 4, within the footprint of the first side 151 of the encapsulation 150, the wall 121 has the greater wall thickness t₁ essentially only directly below the one or more power electronic substrates 130. Any portion of the wall 121 that is arranged directly under the encapsulation 150 essentially has the smaller wall thickness t₂.

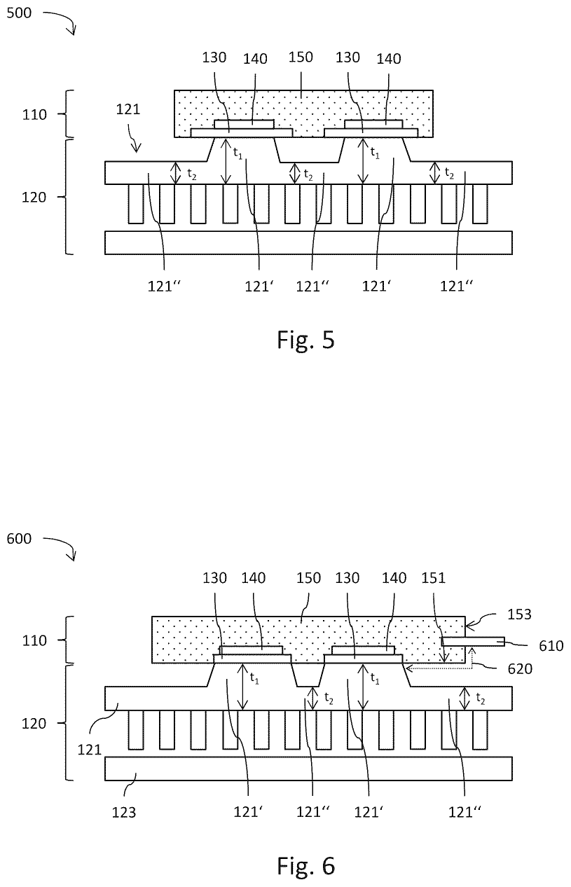

FIG. 5 shows a sectional view of a further power electronic system 500 which may be similar or identical to the power electronic systems 100 and 400, except for the differences described in the following.

In the power electronic system 500, a footprint of the first portions 121′ of the wall 121 is smaller than a footprint of the respective power electronic substrate 130 that is attached to the respective first portion 121′. In particular, the first portions 121′ with the greater wall thickness t₁ are essentially only arranged directly below the footprints of the power semiconductor dies 140.

By reducing the size of the first portions 121′ in this manner, the power electronic substrates 130 may more easily deform in response to thermal stress which in turn may for example reduce body stress in the encapsulation 150. Furthermore, such a reduced size of the first portions 121′ may reduce the amount of e.g. sinter paste or solder material required for coupling the semiconductor module 110 to the cooler 120. Since the first portions 121′ essentially cover the whole footprints of the power semiconductor dies 140, thermal coupling between the power semiconductor dies 140 and the cooler 120 is not negatively affected by the reduction in size of the first portions 121′ in this manner.

FIG. 6 shows a sectional view of a further power electronic system 600 which may be similar or identical to the power electronic systems 100 to 500, except for the differences described in the following.

The semiconductor module 110 of the power electronic system 600 comprises at least one external contact 610 exposed from the encapsulation 150 at one of the lateral sides 153. The external contact 610 may be electrically connected to at least one of the power semiconductor dies 140 (this connection is not shown in FIG. 6). The semiconductor module 110 may comprise any suitable number of external contacts 610. One or more further external contacts 610 may for example be arranged at the same lateral side 153 as the external contact shown in FIG. 6 and/or at another one of the lateral sides 153, for example at the opposite lateral side 153. The one or more external contacts 610 may for example be power contacts, e.g. direct current contacts and/or phase current contacts.

As shown in FIG. 6, a portion of the wall 121 arranged below the external contact 610 has the second wall thickness t₂. For this reason, a creepage distance 620 between the external contact 610 and the cooler 120 comprises not only a portion of the lateral side 153 below the external contact 610 but also a portion of the first side 151 of the encapsulation 150. An electrical isolation between the external contact 610 and the cooler 120 may therefore be improved compared to the case that the semiconductor module 110 touches the cooler 120 directly below the lateral side 153.

According to an example, about 1 mm or more, or 2 mm or more, or 3 mm or more of the first side 151 of the encapsulation 150 contribute to the creepage distance 620. According to an example, about 0.2 mm or more, or 0.5 mm or more, or 0.8 mm or more, or 1 mm or more of the lateral side 153 contribute to the creepage distance 620.

According to an example, the semiconductor module 110 of the power electronic system 600 comprises a first power electronic substrate 130 and a second power electronic substrate 130. In this case, the wall 121 of the cooler 120 may have the second wall thickness t2 between the first and second power electronic substrates 130. In this manner, the flexibility of the wall 121 may be increased and tension due to a mismatch of the coefficients of thermal expansion of the semiconductor module 110 and the cooler 120 may be reduced, as described previously.

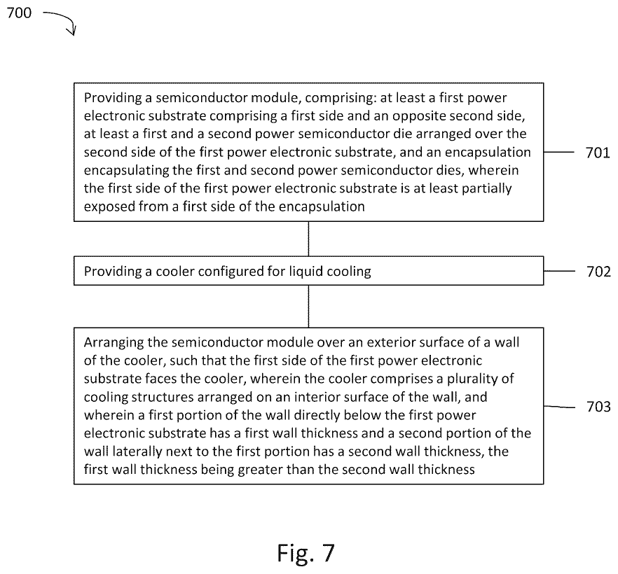

FIG. 7 is a flow chart of an exemplary method 700 for fabricating a power electronic system. The method 700 may for example be used to fabricate the power electronic systems 100 to 600.

The method 700 comprises at 701 a process of providing a semiconductor module, comprising: at least a first power electronic substrate comprising a first side and an opposite second side, at least a first and a second power semiconductor die arranged over the second side of the first power electronic substrate, and an encapsulation encapsulating the first and second power semiconductor dies, wherein the first side of the first power electronic substrate is at least partially exposed from a first side of the encapsulation; the method 700 comprises at 702 a process of providing a cooler configured for fluidic cooling; and at 703 a process of arranging the semiconductor module over an exterior surface of a wall of the cooler, such that the first side of the first power electronic substrate faces the cooler, wherein the cooler comprises a plurality of cooling structures arranged on an interior surface of the wall, and wherein a first portion of the wall directly below the first power electronic substrate has a first wall thickness and a second portion of the wall laterally next to the first portion has a second wall thickness, the first wall thickness being greater than the second wall thickness.

In the following, the power electronic system and the method for fabricating a power electronic system are further explained using specific examples.

Example 1 is a power electronic system, comprising: a semiconductor module, comprising: at least a first power electronic substrate comprising a first side and an opposite second side, at least a first and a second power semiconductor die arranged over the second side of the first power electronic substrate, and an encapsulation encapsulating the first and second power semiconductor dies, wherein the first side of the first power electronic substrate is at least partially exposed from a first side of the encapsulation; and a cooler configured for fluidic cooling, wherein the semiconductor module is arranged over an exterior surface of a wall of the cooler, such that the first side of the first power electronic substrate faces the wall, wherein the cooler comprises a plurality of cooling structures arranged on an interior surface of the wall, and wherein a first portion of the wall directly below the first power electronic substrate has a first wall thickness and a second portion of the wall laterally next to the first portion has a second wall thickness, the first wall thickness being greater than the second wall thickness.

Example 2 is the power electronic system of example 1, wherein at least a portion of the wall arranged within a footprint of the first side of the encapsulation has the second wall thickness.

Example 3 is the power electronic system of example 2, wherein within the footprint of the first side of the encapsulation, the wall has the first wall thickness essentially only directly below any power electronic substrate of the semiconductor module.

Example 4 is the power electronic system example 1 or 2, wherein a portion of the wall defined by footprints of the at least first and second power semiconductor dies has the first wall thickness and another portion of the wall surrounding the footprints of the at least first and second power semiconductor dies has the second wall thickness.

Example 5 is the power electronic system of one of the preceding examples, wherein the encapsulation further comprises a second side opposite the first side and lateral sides connecting the first and second sides, wherein the semiconductor module further comprises at least one external contact exposed from the encapsulation at one of the lateral sides, and wherein a portion of the wall arranged below the external contact has the second wall thickness, such that a creepage distance between the external contact and the cooler comprises a portion of the first side of the encapsulation.

Example 6 is the power electronic system of example 5, wherein along the first side of the encapsulation, the creepage distance has a length of 1 mm or more, in particular 3 mm or more.

Example 7 is the power electronic system of one of the preceding examples, wherein the semiconductor module further comprises: a second power electronic substrate arranged laterally next to the first power electronic substrate, wherein the wall has the first wall thickness directly below the second power electronic substrate, and wherein the wall has the second wall thickness between the first and second power electronic substrates.

Example 8 is the power electronic system of one of the preceding examples, wherein the first wall thickness is in the range of 2 mm to 5 mm and wherein the second wall thickness is in the range of 0.5 mm to 1.8 mm.

Example 9 is the power electronic system of one of the preceding examples, wherein a difference between the first wall thickness and the second wall thickness is in the range of 1 mm to 4 mm.

Example 10 is a method for fabricating a power electronic system, the method comprising: providing a semiconductor module, comprising: at least a first power electronic substrate comprising a first side and an opposite second side, at least a first and a second power semiconductor die arranged over the second side of the first power electronic substrate, and an encapsulation encapsulating the first and second power semiconductor dies, wherein the first side of the first power electronic substrate is at least partially exposed from a first side of the encapsulation; providing a cooler configured for cooling; fluidic and arranging the semiconductor module over an exterior surface of a wall of the cooler, such that the first side of the first power electronic substrate faces the cooler, wherein the cooler comprises a plurality of cooling structures arranged on an interior surface of the wall, and wherein a first portion of the wall directly below the first power electronic substrate has a first wall thickness and a second portion of the wall laterally next to the first portion has a second wall thickness, the first wall thickness being greater than the second wall thickness.

Example 11 is the method of example 10, wherein the wall comprises or consists of Al.

Example 12 is the method of example 10 or 11, wherein arranging the semiconductor module over the cooler comprises sintering the first side of the power electronic substrate to the exterior surface.

Example 13 is an apparatus comprising means for performing the method according to anyone of examples 10 to 12.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

1. A power electronic system, comprising:
a semiconductor module, comprising:
at least a first power electronic substrate comprising a first side and an opposite second side;
at least a first and a second power semiconductor die arranged over the second side of the first power electronic substrate; and
an encapsulation encapsulating the first and second power semiconductor dies, wherein the first side of the first power electronic substrate is at least partially exposed from a first side of the encapsulation; and
a cooler configured for fluidic cooling, wherein the semiconductor module is arranged over an exterior surface of a wall of the cooler, such that the first side of the first power electronic substrate faces the wall,
wherein the cooler comprises a plurality of cooling structures arranged on an interior surface of the wall,
wherein a first portion of the wall directly below the first power electronic substrate has a first wall thickness and a second portion of the wall laterally next to the first portion has a second wall thickness, the first wall thickness being greater than the second wall thickness.

2. The power electronic system of claim 1, wherein at least a portion of the wall arranged within a footprint of the first side of the encapsulation has the second wall thickness.

3. The power electronic system of claim 2, wherein within the footprint of the first side of the encapsulation, the wall has the first wall thickness essentially only directly below any power electronic substrate of the semiconductor module.

4. The power electronic system of claim 1, wherein a portion of the wall defined by footprints of the at least first and second power semiconductor dies has the first wall thickness and another portion of the wall surrounding the footprints of the at least first and second power semiconductor dies has the second wall thickness.

5. The power electronic system of claim 1, wherein the encapsulation further comprises a second side opposite the first side and lateral sides connecting the first and second sides, wherein the semiconductor module further comprises at least one external contact exposed from the encapsulation at one of the lateral sides, and wherein a portion of the wall arranged below the external contact has the second wall thickness, such that a creepage distance between the external contact and the cooler comprises a portion of the first side of the encapsulation.

6. The power electronic system of claim 5, wherein along the first side of the encapsulation, the creepage distance has a length of 1 mm or more.

7. The power electronic system of claim 6, wherein the length is 3 mm or more.

8. The power electronic system of claim 1, wherein the semiconductor module further comprises:
a second power electronic substrate arranged laterally next to the first power electronic substrate,
wherein the wall has the first wall thickness directly below the second power electronic substrate, and
wherein the wall has the second wall thickness between the first and second power electronic substrates.

9. The power electronic system of claim 1, wherein the first wall thickness is in a range of 2 mm to 5 mm, and wherein the second wall thickness is in a range of 0.5 mm to 1.8 mm.

10. The power electronic system of claim 1, wherein a difference between the first wall thickness and the second wall thickness is in a range of 1 mm to 4 mm.

11. A method for fabricating a power electronic system, the method comprising:
providing a semiconductor module that comprises at least a first power electronic substrate comprising a first side and an opposite second side, at least a first and a second power semiconductor die arranged over the second side of the first power electronic substrate, and an encapsulation encapsulating the first and second power semiconductor dies, wherein the first side of the first power electronic substrate is at least partially exposed from a first side of the encapsulation;
providing a cooler configured for fluidic cooling; and
arranging the semiconductor module over an exterior surface of a wall of the cooler, such that the first side of the first power electronic substrate faces the cooler,
wherein the cooler comprises a plurality of cooling structures arranged on an interior surface of the wall,
wherein a first portion of the wall directly below the first power electronic substrate has a first wall thickness and a second portion of the wall laterally next to the first portion has a second wall thickness, the first wall thickness being greater than the second wall thickness.

12. The method of claim 11, wherein the wall comprises or consists of Al.

13. The method of claim 11, wherein arranging the semiconductor module over the cooler comprises sintering the first side of the power electronic substrate to the exterior surface.
